(19) United States
(12) Patent Application Publication
(10) Pub. No.: US 2008/0223431 A1
(43) Pub. Date: Sep. 18, 2008

(54) Foldable solar panel

(76) Inventor: Raymond Chu, Jhongli City (TW)

Correspondence Address: Hershkovitz & Associates, LLC, 2845 Duke Street, Alexandria, VA, 22314, US

(21) Appl. No.: 11/724,159

(22) Filed: Mar. 15, 2007

(51) Int. Cl. H01L 31/045

(52) U.S. Cl. 136/245

(57) ABSTRACT

A foldable solar panel comprises multiple rigid cell assemblies, multiple folding cell assemblies and multiple primary flexible seams. Each folding cell assembly has two symmetric folding cell assembly halves and a flexible secondary seam. The symmetric folding cell assembly halves are adjacent to each other. The secondary flexible seam connects adjacent symmetric folding cell assembly halves and allows them to fold inward onto each other. A primary flexible seam connects a rigid cell assembly to an adjacent folding cell assembly to form an absorbing surface. The primary flexible seams and secondary flexible seams facilitate folding the foldable solar penal to a small volume to facilitate transportation or storage, and effectively keep the absorbing surface from being damaged.

### BACKGROUND OF THE INVENTION

1. Field of the Invention

The present invention relates to a solar collector, and more particular to a foldable solar panel that is convenient to transport or store.

2. Description of Related Art

A solar collector is a device for collecting energy from the sun direct use or storage.

Generally, a solar collector has at least one solar panel that is mounted securely on a frame and is mounted in a determined place facing the sky like a roof. The solar panel has multiple cells mounted securely on the solar panel to form an absorbing surface and absorb solar energy striking the absorbing surface. Thus, more solar energy striking the absorbing surface of the solar panel results in more power being provided by the solar collector.

However, solar energy striking the solar panel's absorbing surface at any one time depends on weather conditions, location and orientation of the absorbing surface of the solar panel. Since a conventional solar panel is usually heavy and quite large, moving or transporting a solar panel to adjust position or orientation relative to the sun may be very inconvenient.

Moreover, conventional solar panels are difficult to move away from the frame and the absorbing surface is exposed all the time. Consequently covering or storing the solar panel during the sudden onset of a typhoon, rain, snow or hail may be difficult or impossible, which could easily lead to the absorbing surface of the solar panels being damaged.

To overcome the shortcomings, the present invention provides a foldable solar panel to obviate or mitigate the aforementioned problems.

### SUMMARY OF THE INVENTION

The main objective of the present invention is to provide a foldable solar panel that can be folded and is convenient to transport, and effectively prevents solar energy absorbing surfaces from being damaged.

To achieve the objective, the foldable solar panel in accordance with present invention comprises multiple rigid cell assemblies, multiple folding cell assemblies and multiple primary flexible seams. Each folding cell assembly has two symmetric folding cell assembly halves and a flexible secondary seam. The symmetric folding cell assembly halves are adjacent to each other. The secondary flexible seam connects adjacent symmetric folding cell assembly halves and allows them to fold inward onto each other. A primary flexible seam connects a rigid cell assembly to an adjacent folding cell assembly to form an absorbing surface.

The primary flexible seams and secondary flexible seams facilitate folding the foldable solar penal to a small volume to facilitate transportation or storage and effectively keep the absorbing surface from being damaged.

Other objectives, advantages and novel features of the invention will become more apparent from the following detailed description when taken in conjunction with the accompanying drawings.

### BRIEF DESCRIPTION OF THE DRAWINGS

FIG. 1 is a top view of a first embodiment of a foldable solar panel in accordance with the present invention mounted on a frame;

FIG. 2 is an operational top view of the foldable solar panel in FIG. 1 with folding cell assemblies being folded;

FIG. 3 is another operational top view of the foldable solar panel in FIG. 1 with cell assemblies folded inward to protect absorbing surfaces of the solar panel;

FIG. 4 is a top view of the foldable solar panel in FIG. 1 in a folded status;

FIG. 5 is an operational side view in partial section of a foldable solar panel in FIG. 1 folded and secured to a frame with two belts;

FIG. 6 is a top view of a second embodiment of a foldable solar panel in accordance with the present invention;

FIG. 7 is an operational top view of the foldable solar panel in FIG. 6 with the folding cell assemblies being folded;

FIG. 8 is another operational top view of the foldable solar panel in FIG. 6 with cell assemblies folded inward to protect absorbing surfaces of the solar panel;

FIG. 9 is a top view of the foldable solar panel in FIG. 6 in a folded status;

FIG. 10 is a top view of a third embodiment of a foldable solar panel in accordance with the present invention;

FIG. 11 is an operational top view of the foldable solar panel in FIG. 10 with the folding cell assemblies being folded;

FIG. 12 is another operational top view of the foldable solar panel in FIG. 10 the cell assemblies folded inward to protect absorbing surfaces of the solar panel; and

FIG. 13 is a top view of the foldable solar panel in FIG. 10 in a folded status.

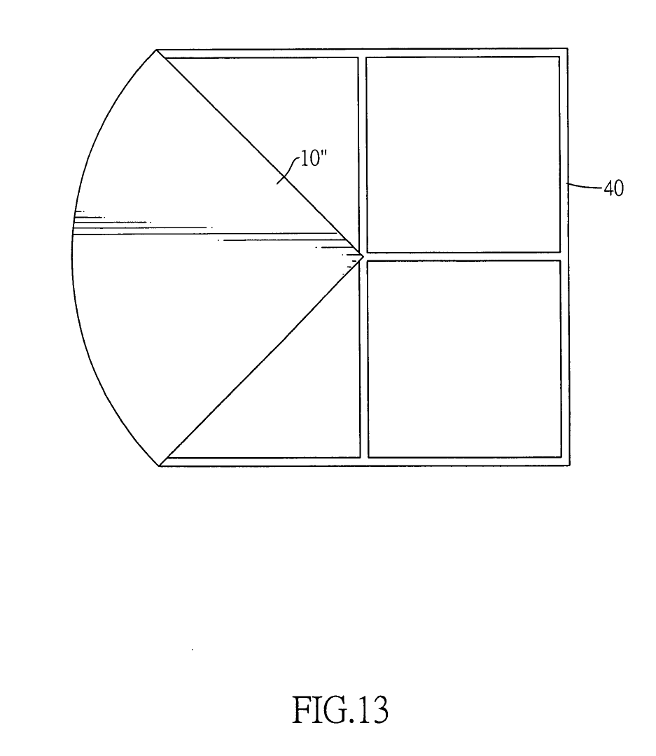

### DETAILED DESCRIPTION OF THE PREFERRED EMBODIMENT

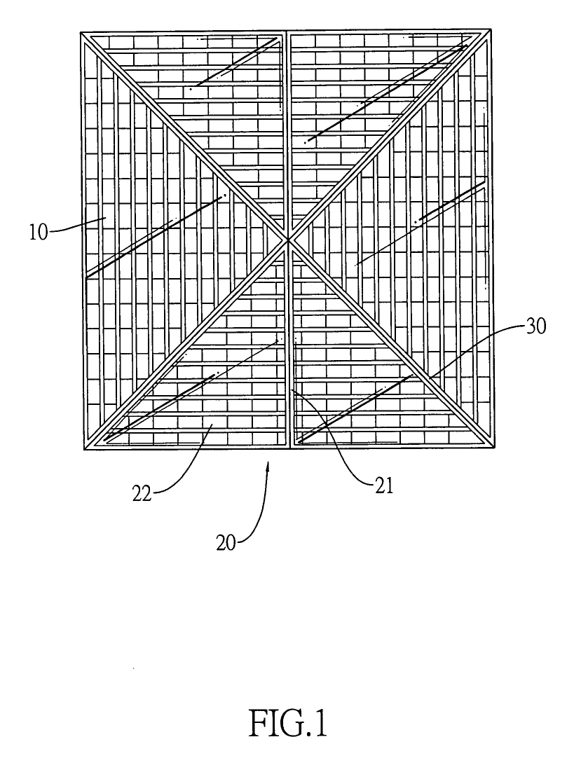

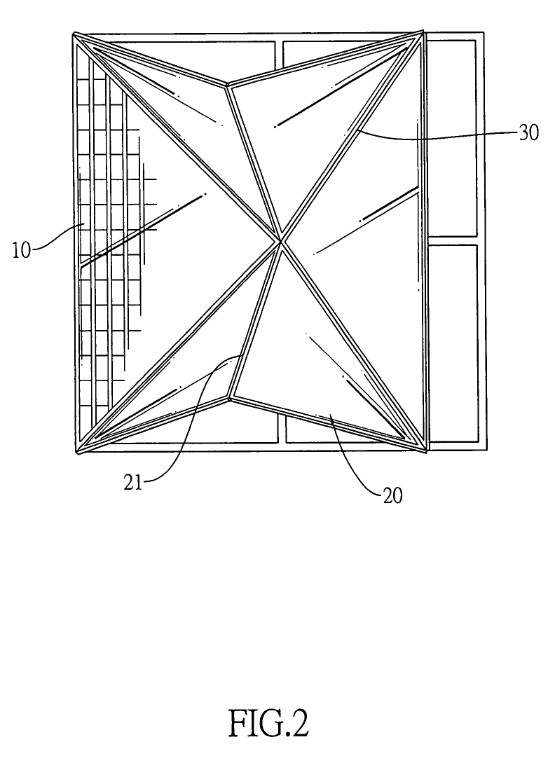

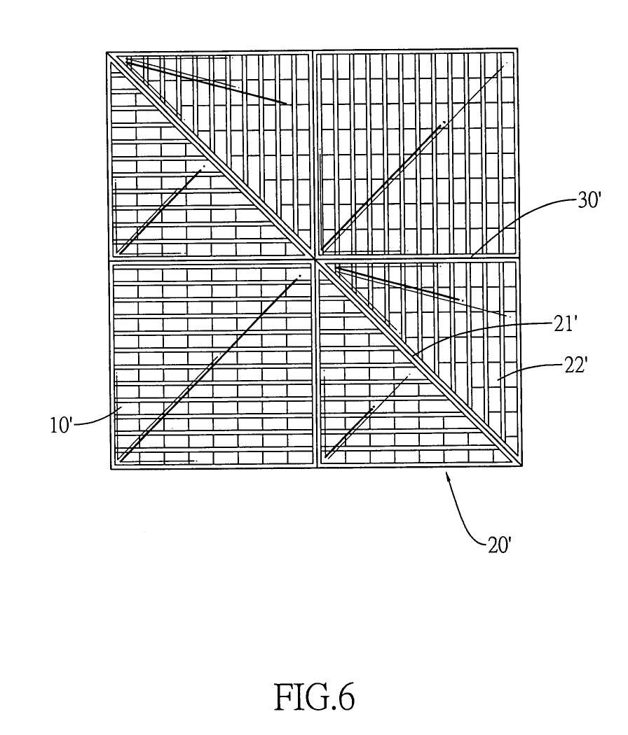

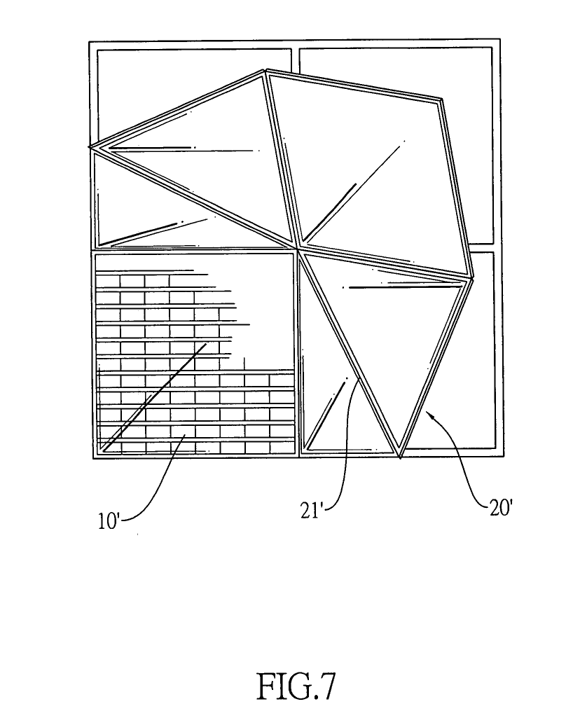

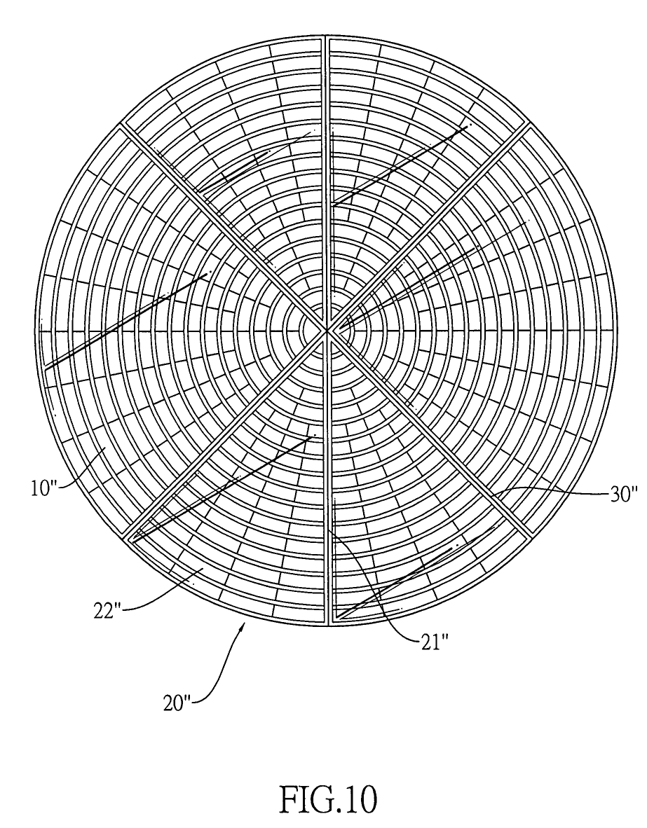

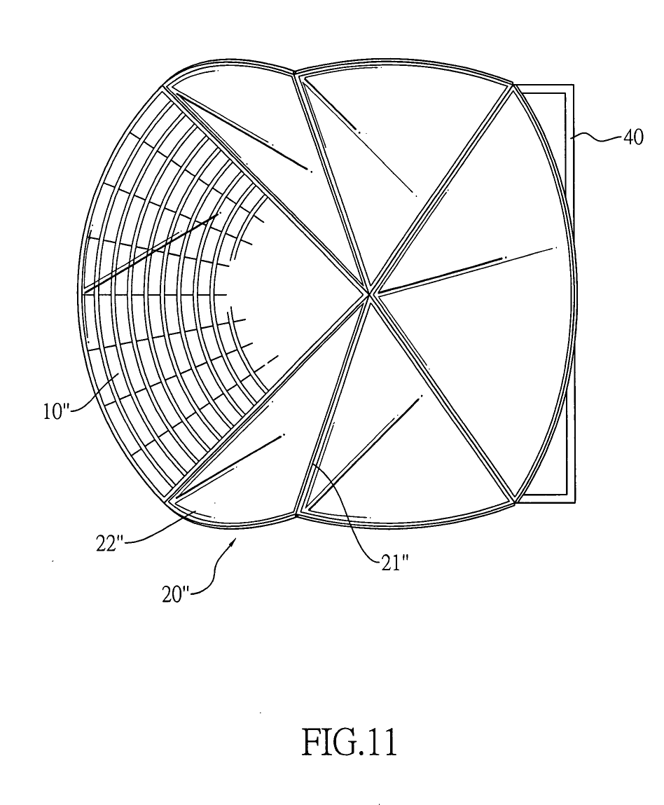

With reference to FIGS. 1, 2, 6, 7, 10 and 11, a foldable solar panel in accordance with present invention is mounted detachably on a frame (40), and comprises at least two rigid cell assemblies (10, 10′, 10″), a corresponding number of folding cell assemblies (20, 20′, 20″) and multiple primary flexible seams (30, 30′, 30″).

The rigid cell assemblies (10, 10′, 10″) are mounted opposite to each other and may be triangular, square or sectorial, and each rigid cell assembly (10, 10′, 10″) has two side edges.

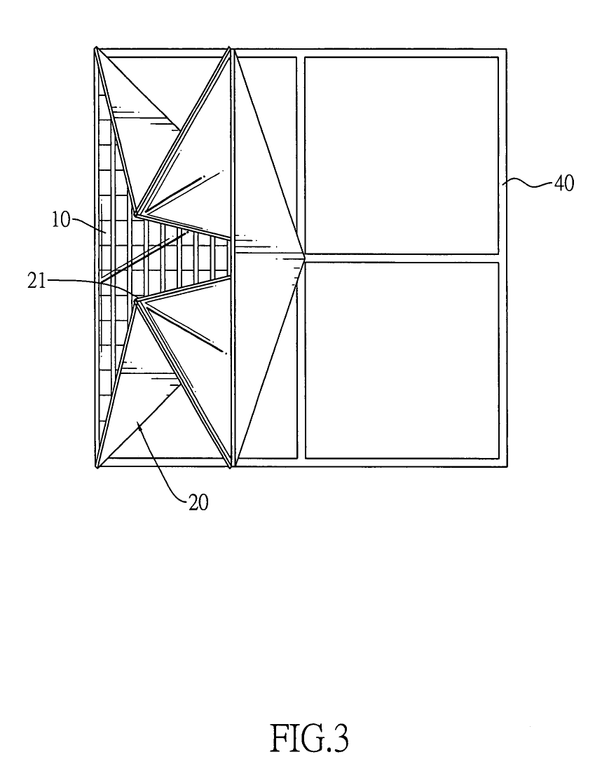

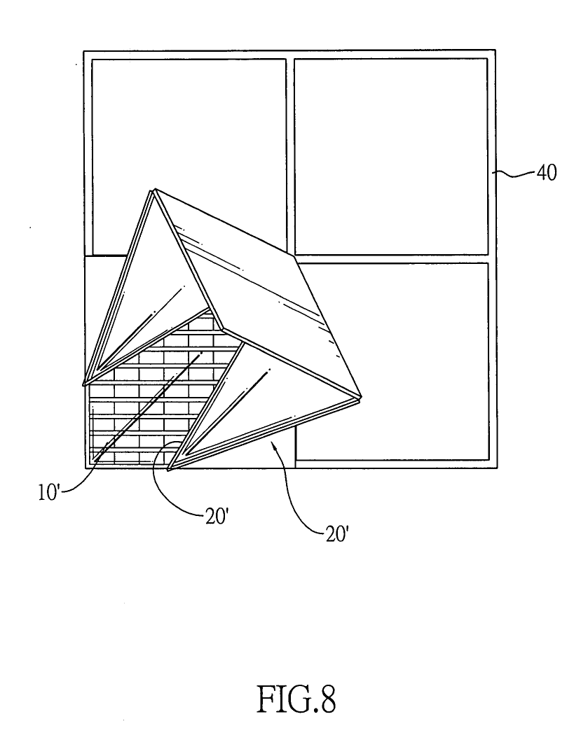

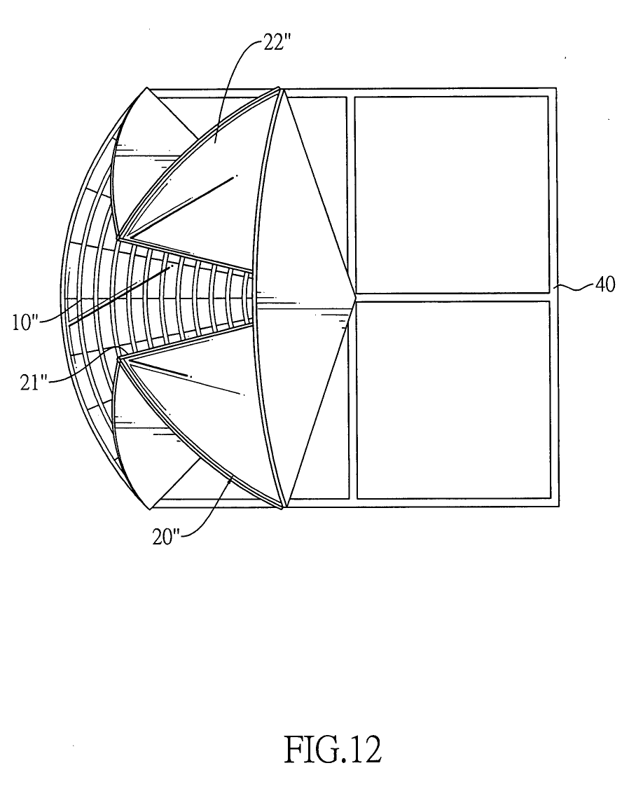

The folding cell assemblies (20, 20′, 20″) may be triangular, square or sectorial are mounted opposite to each other between the rigid cell assemblies (10, 10′, 10″), and each folding cell assembly (20, 20′, 20″) has two symmetric folding cell assembly halves (22, 22′, 22″) and a secondary flexible seam (21, 21′, 21″). The symmetric folding cell assembly halves (22, 22′, 22″) are mounted adjacent to each other, and each symmetric folding cell assembly half (22, 22′, 22″) has an inner side edge and an outer side edge. The inner side edges are adjacent to each other. The outer side edges are adjacent respectively to the side edges of the adjacent rigid cell assemblies (10, 10′, 10″). With further reference to FIGS. 3, 8 and 12,13, the secondary flexible seam (21, 21′, 21″) is bendable, may be a rubber sheet or a metal hinge, connects the inner edges of adjacent symmetric folding cell assembly halves (22, 22′, 22″) and allows the symmetric folding cell assembly halves (22, 22′, 22″) to fold inward.

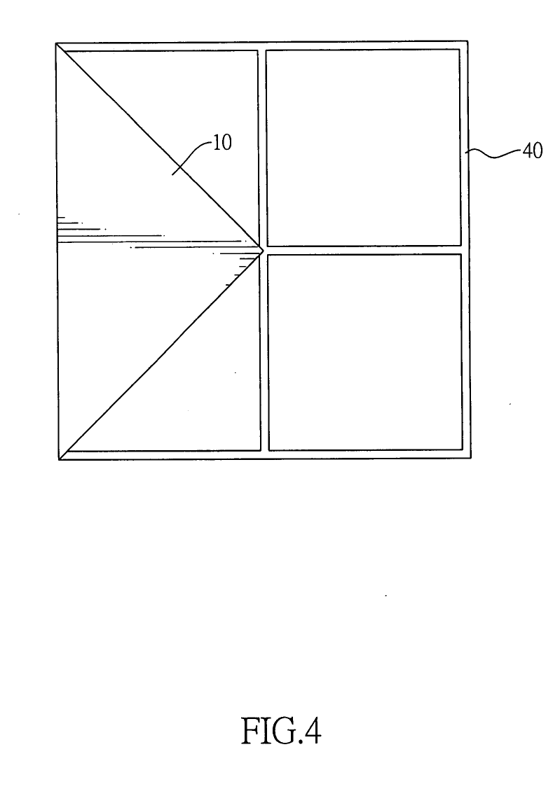

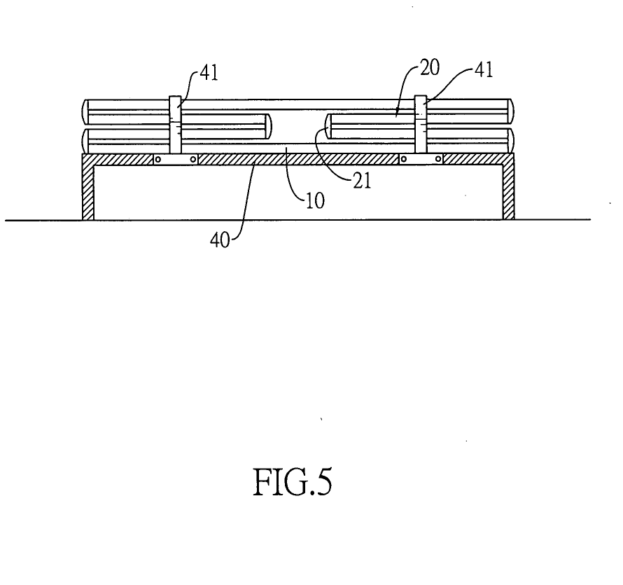

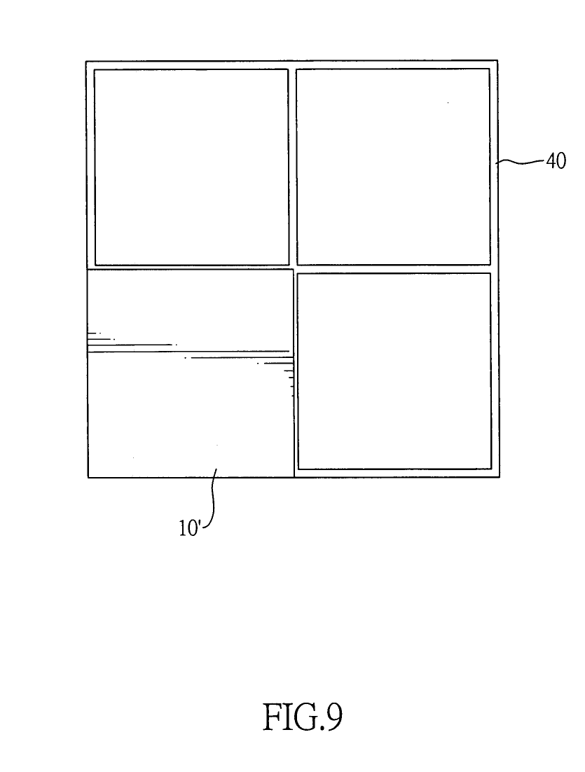

The primary flexible seams (30, 30′, 30″) are bendable and may be rubber sheets or metal hinges, and a primary flexible seam (30, 30′, 30″) connects a side edge of a rigid cell assembly (10, 10′, 10″) to the adjacent outer side edge of the adjacent symmetric folding cell assembly half (22, 22′, 22″) so the rigid cell assemblies (10, 10′, 10″) and the folding cell assemblies (20, 20′, 20″) a square or round absorbing surface to absorb solar energy. With further reference to FIGS. 4, 5 and 9, the primary flexible seams (30, 30′, 30″) in conjunction with the secondary flexible seams (21, 21′, 21″) allow the solar panel to be conveniently folded to a small volume with the absorbing surfaces inside and protected such that straps (41) attached to the frame (40) securely hold the solar panel in a folded state.

Even though numerous characteristics and advantages of the present invention have been set forth in the foregoing description together with details of the structure and function of the invention, the disclosure is illustrative only. Changes may be made in detail especially in matters of shape, size and arrangement of parts within the principles of the invention to the full extent indicated by the broad general meaning of the terms in which the appended claims are expressed.

What is claimed is:

1. A foldable solar panel comprising
at least two rigid cell assemblies being mounted opposite to each other, and each one of the at least two rigid cell assembly having two side edges;
a corresponding number of folding cell assemblies being mounted opposite to each other between the rigid cell assemblies, and each folding cell assembly having
two symmetric folding cell assembly halves being mounted adjacent to each other, and each symmetric folding cell assembly half having
an inner side edge, the inner side edges being adjacent to each other; and
an outer side edge, the outer side edges being adjacent respectively to the side edges of the adjacent rigid cell assemblies; and
a secondary flexible seam being bendable and connecting the inner edges of the adjacent symmetric folding cell assembly halves and allowing the symmetric folding cell assembly halves to fold inward; and
multiple primary flexible seams being bendable, and a primary flexible seam connects a side edge of a corresponding rigid cell assembly to the adjacent outer side edge of the adjacent symmetric folding cell assembly half.

2. The foldable solar panel as claimed in claim 1, wherein
the rigid cell assemblies are triangular; and
the folding cell assemblies are triangular.

3. The foldable solar panel as claimed in claim 1, wherein
the rigid cell assemblies are square; and
the folding cell assemblies are square.

4. The foldable solar panel as claimed in claim 1, wherein
the rigid cell assemblies are sectorial; and
the folding cell assemblies are sectorial.

5. The foldable solar panel as claimed in claim 1, wherein
each primary flexible seam is a rubber sheet; and
each secondary flexible seam is a rubber sheet.

6. The foldable solar panel as claimed in claim 1, wherein
each primary flexible seam is a metal hinge; and
each secondary flexible seam is a metal hinge.
